(19) United States
(12) Patent Application Publication
(10) Pub. No.: US 2023/0272279 A1
(43) Pub. Date: Aug. 31, 2023

(54) RUTHENIUM ETCHANT COMPOSITION, PATTERN FORMATION METHOD USING SAME COMPOSITION, METHOD OF MANUFACTURING ARRAY SUBSTRATE, AND ARRAY SUBSTRATE MANUFACTURED THEREBY

(71) Applicants: DONGWOO FINE-CHEM CO., LTD., Iksan-si (KR); SAMSUNG ELECTRONICS CO., LTD, Suwon-si (KR)

(72) Inventors: Ji-Won Kim, Iksan-si (KR); Jin-Kyu Roh, Iksan-si (KR); Hyo-Joong Yoon, Iksan-si (KR); Han-Woo Park, Iksan-si (KR); Min-Jae Sung, Seoul (KR); Soo-Jin Kim, Seoul (KR); Jung-Min Oh, Incheon (KR); Sang-Won Bae, Suwon-si (KR)

(21) Appl. No.: 18/176,215

(22) Filed: Feb. 28, 2023

(30) Foreign Application Priority Data
Feb. 28, 2022 (KR) 10-2022-0025677

(51) Int. Cl. C09K 13/06

(52) U.S. Cl. CPC C09K 13/06; H01L 21/32134

(57) ABSTRACT

Disclosed is a ruthenium etchant composition containing periodic acid and ammonium ions and having a pH of 6 to 7.5. Further disclosed are a pattern formation method including a step of etching a ruthenium metal film using the etchant composition, a method of manufacturing a display device array substrate by employing the pattern formation method, and a display device array substrate manufactured by the method.

### CROSS-REFERENCE TO RELATED APPLICATION

This application claims priority to Korean Patent Application Serial No. KR 10-2022-0025677, filed Feb. 28, 2022, for “Ruthenium Etchant Composition, Pattern Formation Method Using Same Composition, Method of Manufacturing Array Substrate, and Array Substrate Manufactured Thereby,” the disclosure of which is hereby incorporated herein in its entirety by this reference.

### TECHNICAL FIELD

The present disclosure relates to a ruthenium etchant composition, a pattern formation method including a step of etching a ruthenium metal film using the etchant composition, a method of manufacturing an array substrate for a display device by employing the pattern formation method, and a display device array substrate manufactured by the method.

### BACKGROUND

Ruthenium (Ru) maintains conductivity even in an oxidized state, does not cause capacity degradation, and is relatively cheap. Therefore, Ru has recently attracted as an alternative to tungsten (W) in applications such as thin film transistor gate electrodes, interconnects, barrier layers, and plugs for filling contact holes, via holes, etc.

When forming interconnects, via holes, etc. on a semiconductor substrate, a process of removing unnecessary parts while leaving only necessary parts is required. In particular, since a technique of forming an electrode film in a narrow hole is frequently employed to reduce the area occupied by a capacitor, the development of an etchant composition enabling the formation of a uniform thin ruthenium metal film in a narrow hole is required.

When a ruthenium metal film is etched with an acidic etchant composition, there are cases where RuO₄, which is a toxic gas, is generated. Therefore, it is preferable to etch a ruthenium metal film in a neutral or alkaline environment. However, when an etchant composition having an excessive high pH is used for ruthenium etching to reduce the generation of RuO₄, the stability of periodic acid serving as an oxidizing agent is lowered and the etch rate is reduced. To prevent the reduction in etch rate, a method of increasing a reaction temperature may be considered. However, the elevated reaction temperature cannot solve the problem of RuO₄ generation. Therefore, it is necessary to develop an etchant composition having a suitable pH range and being capable of etching a ruthenium metal film at room temperature.

In the semiconductor industry, it is common that the manufacturers hold raw materials for several months in stock to maintain the process continuity and stability. Therefore, it is required that etchants can be stably preserved at room temperature for a long period of time. In particular, in the case of ruthenium etching, it is usually carried out in a single-type equipment, and the amount of an etchant used for one etching operation is relatively small. Therefore, it is common that an etchant for ruthenium etching is stored in an equipment tank for a long period of time, for example, three months. Therefore, a ruthenium etchant composition is required to have excellent storage stability compared to etchant compositions for other metals.

For example, Korean Patent Application Publication No. 10-2022-0051230 discloses a RuO₄ gas generation inhibitor containing an onium salt and having a pH value in a range of from 8 to 14.

When a ruthenium metal film is etched with an alkaline etchant composition having a pH of 8 or higher, the production of RuO₄ gas is inhibited. However, in such a case, the etch rate of the ruthenium metal film and the storage stability of the etchant composition at room temperature are remarkably deteriorated, resulting in poor selectivity to the ruthenium metal film.

Therefore, there is a need for a ruthenium etchant composition having a pH value in an appropriate range (neutral to alkaline) to inhibit the generation of RuO₄ gas, to guarantee a good etch rate for a ruthenium metal film, and to improve storage stability at room temperature.

Document of Related Art

(Patent Document)

Korean Patent Application Publication No. 10-2022-0051230

### BRIEF SUMMARY

An objective of the present disclosure is to provide a ruthenium etchant composition being capable of rapidly selectively etching only a ruthenium metal film without generating RuO₄ gas and having excellent storage stability at room temperature.

To achieve the above objective, one embodiment of the present disclosure provides a ruthenium etchant composition containing periodic acid and ammonium ions and having a pH value in a range of 6 to 7.5.

According to one embodiment of the present disclosure, a ruthenium etchant composition includes periodic acid and ammonium ions and has a pH value in the range of from 6 to 7.5, thereby suppressing RuO₄ gas generation even without using a RuO₄ gas generation inhibitor.

In addition, according to one embodiment of the present disclosure, a ruthenium etchant composition has a pH value in the range of from 6 to 7.5 and contains periodic acid and ammonium ions, thereby exhibiting a high etch rate with respect to a ruthenium metal film.

In addition, according to one embodiment of the present disclosure, a ruthenium etchant composition is controlled to have a pH value in the range of from 6 to 7.5, thereby having improved storage stability at room temperature.

### DETAILED DESCRIPTION

The present disclosure relates to a ruthenium etchant composition including periodic acid and ammonium ions and having a pH value in the range of from 6 to 7.5. The ruthenium etchant composition inhibits the generation of RuO₄ gas even without including a RuO₄ gas generation inhibitor, exhibits an increased etch rate for a ruthenium metal film, and has improved storage stability at room temperature.

More specifically, the present disclosure relates to a ruthenium etchant composition including periodic acid and ammonium ions.

The present disclosure also relates to a pattern formation method including a step of etching a ruthenium metal film using the ruthenium etchant composition, a method of manufacturing an array substrate for a display device by employing the pattern formation method, and a display device array substrate manufactured by the method.

The ruthenium etchant composition according to one embodiment of the present disclosure is especially suitable for use in the technical field of selectively etching and removing a ruthenium metal film. For example, the ruthenium etchant composition can be used to selectively rapidly remove a ruthenium metal film from a microelectronic device including a silicon oxide film and an insulating material as well as the ruthenium metal film.

Specifically, when a ruthenium metal film is etched with the ruthenium etchant composition according to one embodiment of the present disclosure, the etch rate of the ruthenium metal film may be 200 Å/min or more, and a reduction in the etch rate may be 5% or less after 3 months of storage of the ruthenium etchant composition in a temperature range of 20° C. to 25° C.

The ruthenium metal film, which is an etching target to be etched with the etchant composition according to one embodiment of the present disclosure, refers to a metal film containing ruthenium. For example, the ruthenium metal film may be a single-layered film made of ruthenium, ruthenium alloy, or ruthenium oxide, or a multi-layered film including at least one selected from the group consisting of the single-layered film, a silicon film, and a barrier film.

In addition, the silicon film may include at least one film selected from the group consisting of a silicon oxide film, a silicon nitride film, a silicon carbide oxide film, a silicon carbide film, and a silicon nitride film, and the barrier film may include at least one selected from the group consisting of a titanium nitride film and a tantalum nitride film.

Hereinafter, embodiments of the present disclosure will be described in greater detail.

The terminology used herein is for describing embodiments and is not intended to limit the present disclosure.

It will be further understood that the terms “comprise” and/or “comprising” when used in this specification specify the presence of stated features, regions, integers, steps, operations, elements and/or components, but do not preclude the presence or addition of one or more other features, regions, integers, steps, operations, elements, components and/or groups thereof. Like reference numbers refer to like elements throughout the description herein and the drawings.

Ruthenium Etchant Composition

A ruthenium etchant composition according to one embodiment of the present disclosure includes periodic acid and ammonium ions and has a pH value in the range of from 6 to 7.5. In addition, the ruthenium etchant composition according to one embodiment of the present disclosure may further include a hydroxide of quaternary alkyl ammonium.

The periodic acid functions to oxidize ruthenium and to etch a ruthenium metal film. The periodic acid oxidizes ruthenium to produce RuO₄⁻ or RuO₄²⁻. When a ruthenium metal film is etched using an acidic etchant composition, RuO₄, which is a toxic gas, may be generated. However, since the etchant composition according to one embodiment of the present disclosure is neutral or alkaline (i.e., having a pH value in the range of 6 to 7.5), the etchant composition can selectively etch a ruthenium metal film even without addition of a RuO₄ gas generation inhibitor.

According to one or more embodiments, the periodic acid includes periodic acid (H₅IO₆ or HIO₄) and a salt form thereof, and examples of the salt form of the periodic acid include potassium periodate (KIO₃), tetraethylammonium periodate (N(CH₂CH₃)₄IO₃), and tetrabutylammonium periodate (N(CH₂CH₂CH₂CH₃)₄IO₃) but are not limited thereto.

According to one or more embodiments, the amount of periodic acid is 0.1% to 5% by weight and is preferably 0.5% to 3% by weight, based on the total weight of the etchant composition. When the content of the periodic acid is less than 0.1% by weight based on the total weight of the etchant composition, the etch rate of the ruthenium metal film is reduced due to a decrease in oxidizing power of the periodic acid. On the other hand, when the content of the periodic acid exceeds 5% by weight, mixing stability is deteriorated.

The ammonium ions are cations with the chemical formula “NH⁴⁺.” The ammonium ions determine the pH of the etchant composition according to one embodiment of the present disclosure and electrically interact with anions present on the surface of the ruthenium oxide film, so that the etching of the ruthenium metal film is promoted by the periodic acid.

According to one or more embodiments, the ammonium ions can be understood as a concept including a combined form of ammonium ions and anions (i.e., a source of ammonium ions) so that the combined form is dissociated in an aqueous solution to generate ammonium ions. Here, examples of the anions include acetate (C₂H₃O₄), sulfate (SO₄²⁻), sulfamate (H₂NO₃S), formate (CHO₂⁻), oxalate (C₂O₄²⁻), benzoate (C₇H₅O₂⁻), persulfate (SO₅²⁻ or S₂O₈²⁻), carbonate (CO₃²⁻), carbamate (NH₂COO⁻), chloride (Cl), and phosphate (PO₄²⁻) but are not limited thereto.

According to one or more embodiments, the ammonium ions bonded to anions may be at least one selected from ammonium acetate, ammonium sulfate, ammonium sulfamate, ammonium formate, ammonium oxalate, ammonium benzoate, ammonium persulfate, ammonium carbonate, ammonium carbamate, ammonium chloride, and ammonium phosphate.

According to one or more embodiments, the ammonium ion may not include ammonia (NH₃) and/or ammonium hydroxide (NH₄OH). That is, the ammonium ion means only a cation with a chemical forma of NH₄ and may not include ammonia (NH₃) or ammonium hydroxide (NH₄OH) produced by an acid-base reaction. When ammonia (NH₃) and/or ammonium hydroxide (NH₄OH) are added as ammonium ions, hydroxyl groups (OH⁻) dissociated from ammonia (NH₃) and/or ammonium hydroxide contribute to the pH increase of the etchant composition, thereby reducing the etch rate of the ruthenium metal film.

According to one or more embodiments, the content of the ammonium ions or the content of a compound, which is a combined form of ammonium ions and anions, is 0.1% to 5% by weight and is preferably 0.5% to 3% by weight, based on the total weight of the etchant composition. When the content of ammonium ions (or compound, which is a combined form of ammonium ions and anions) is less than 0.1% by weight based on the total weight of the etchant composition, the electrical interaction with the negative electric charge on the surface of the ruthenium oxide film is insufficient, and thus the rate at which the ruthenium metal film is etched by periodic acid is reduced. When the content of ammonium ions (or compound, which is a combined form of ammonium ions and anions) exceeds 5% by weight based on the total weight of the etchant composition, the content of hydroxide of a quaternary alkyl ammonium to be described later needs to be increased to make the pH of the etchant composition to fall within the range of 6 to 7.5. However, the large steric hindrance of the hydroxide of quaternary alkyl ammonium prevents the surface of the ruthenium oxide film from being corroded and thus reduces the etch rate of the ruthenium metal film.

The pH of the ruthenium etchant composition according to one embodiment of the present disclosure may be 6 or more and 7.5 or less. When the pH of the ruthenium etchant composition according to one embodiment of the present disclosure is lower than 6, which means that the ruthenium etchant composition is acidic, periodic acid may oxidize ruthenium to produce RuO₄, which is toxic and volatile. On the other hand, when the pH exceeds 7.5, the stability of periodic acid is rapidly lowered and thus the etch rate of the ruthenium film is reduced. In addition, since periodic acid is reduced to H₃IO₆²⁻, H₂I₂O₁₀⁴⁻, H₂IO₆³⁻, etc., the etching performance and storage stability of the etchant at room temperature are deteriorated. In this case, the term “room temperature” refers to a temperature range of from 20° C. to 25° C.

Conventional ruthenium etchant compositions were neutral or had a pH value of 8 or higher, which means an alkaline state, to prevent the generation of RuO₄ gas. However, when a ruthenium film is etched with a pH-8 ruthenium etchant composition stored at room temperature for a predetermined period of time or longer, the etch rate of the ruthenium film is significantly reduced compared to the case where the ruthenium film is etched with the same etchant being in a fresh state. This results in an increase in the cost of the ruthenium film etching process. Accordingly, the ruthenium etchant composition according to one embodiment of the present disclosure is controlled to have a pH value in the range of from 6 to 7.5, which is lower than pH 8. This ruthenium etchant composition does not generate RuO₄ gas during etching of a ruthenium metal film and has improved storage stability at room temperature. Specifically, when a ruthenium metal film is etched with the ruthenium etchant composition according to one embodiment of the present disclosure, the etch rate of the ruthenium metal film is 200 Å/min and is preferably 300 Å/min. In the case where the ruthenium etchant composition is stored in a temperature range of 20° C. to 25° C. for 72 hours or longer, and a ruthenium metal film is etched with this ruthenium etchant composition, a decrease in the etch rate of the ruthenium metal film is 10% or less and is preferably 5% or less.

According to one embodiment, the pH is controlled by the addition of periodic acid and ammonium ions. Specifically, periodic acid exhibits a pH of 2 and ammonium ions have a pKa of about 9.3 at 25° C. Therefore, those who are ordinarily skilled in the art can control the pH of the etchant to fall within the range of 6 to 7.5 by adding the periodic acid and ammonium ions in an amount in a range of 1% to 5% by weight based on the total weight of the etchant composition.

According to another embodiment of the present disclosure, the ruthenium etchant composition may further include a quaternary alkyl ammonium to control the pH to fall within the range of 6 to 7.5. Specifically, since the quaternary alkyl ammonium dissociates in an aqueous solution to generate hydroxide ions (OH⁻), the quaternary alkyl ammonium can play a role in adjusting the pH of the etchant composition in conjunction with periodic acid and ammonium ions.

According to one or more embodiments, the hydroxide of the quaternary alkyl ammonium is tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltrimethylammonium hydroxide, diethyldimethylammonium hydroxide, hexadecyltrimethylammonium hydroxide, and methyltributylammonium hydroxide, but is not limited thereto.

In addition, the hydroxide of the quaternary alkyl ammonium may prevent the corrosion of a ruthenium metal film by interrupting an electrical interaction between an ammonium ion (NH₄⁺) and an anion present on the surface of the ruthenium oxide film by using a large steric hindrance of an alkyl group.

According to one or more embodiments, the content of the hydroxide of the quaternary alkyl ammonium is in the range of from 0.1% to 2% by weight and is preferably the range of from 0.5% to 1% by weight, based on the total weight of the ruthenium etchant composition. When the content of the hydroxide of the quaternary alkyl ammonium is out of the above-described range, etching performance may be deteriorated and processing time may be increased.

The ruthenium etchant composition according to one embodiment of the present disclosure may be in the form of an aqueous solution containing water, and the water is preferably deionized water for use in semiconductor processing, and more preferably deionized water having a resistivity of 18 MΩ/cm or more.

According to one or more embodiments, the water may be included in a residual amount. As used herein, the term “residual amount” may mean an amount that is added to make the total amount of the composition including essential components and other components becomes equal to 100% by weight.

On the other hand, the ruthenium etchant composition according to one embodiment of the present disclosure may further include other compounds within a range that does not impair the objective of the present disclosure, but it is preferable that the ruthenium etchant composition does not contain a compound that generates fluorine ions (F⁻), for example, hydrogen fluoride (HF). When the etchant composition contains a compound that generates fluorine ions (F⁻), there is a problem in that underlying layers such as a silicon film or a barrier layer are damaged.

In addition to the ruthenium etchant composition, the present disclosure also relates to a pattern formation method including a step of etching a ruthenium metal film using the ruthenium etchant composition, a method of manufacturing an array substrate for a display device by employing the pattern formation method, and a display device array substrate manufactured by the method.

Pattern Formation Method

The present disclosure provides a pattern formation method including the step of etching a ruthenium metal film using the etchant composition according to one embodiment of the present disclosure.

The pattern formation method may be appropriately performed by those who are ordinarily skilled in the art by using a method known in the art. For example, the pattern formation method may include: a step of forming a metal film on a substrate; and depositing and/or spraying the etchant composition according to one embodiment of the present disclosure on the metal film in a batch-type or single-type etching apparatus.

Array Substrate for Display Device and Manufacturing Method Thereof

The present disclosure provides a method of manufacturing an array substrate for a display device by employing the pattern formation method according to one embodiment of the present disclosure and a display device array substrate manufactured by the manufacturing method.

The array substrate for a display device will be manufactured by a known array substrate manufacturing method, except that the etchant composition according to one embodiment of the present disclosure is used. For example, the array substrate manufacturing method may include a) forming a gate electrode on a substrate; b) forming a gate insulating layer on the substrate including the gate electrode; c) forming a semiconductor layer (a-Si:H) on the gate insulating layer; d) forming source/drain electrodes on the semiconductor layer; and e) forming a pixel electrode connected to the drain electrode. In the method, the step b) of forming the gate electrode and the step d) of forming the source/drain electrodes may include forming a ruthenium metal film on the substrate and etching the ruthenium metal film using the etchant composition according to one embodiment of the present disclosure.

The array substrate for a display device may include a substrate manufactured according to the above-described manufacturing method and elements including the same. For example, the array substrate may be a thin film transistor (TFT) array substrate.

Hereinafter, specific examples of the present disclosure will be described. The disclosure may, however, be embodied in many different forms and should not be construed as being limited to the examples set forth herein. Rather, these examples are provided so that the present disclosure will be thorough and complete and will fully convey the concept of the present disclosure to those skilled in the art. Thus, the present disclosures will be defined only by the appended claims.

### Preparation of Ruthenium Etchant Composition: Examples 1 and 31 and Comparative Examples 1 to 17

Ruthenium etchant compositions of Examples 1 to 31 and Comparative Examples 1 to 17, including the components and the residual amount of water as shown in Tables 1 and 2, were prepared (unit: % by weight).

TABLE 1

| | | | | | Hydroxide of | | |
|---|---|---|---|---|---|---|---|
| | | | | | quaternary alkyl | | |
| | Periodic acid | | Ammonium ion | | ammonium | | |
| | Component | Content | Component | Content | Component | Content | pH |
| Example 1 | A-1 | 0.5 | B-1 | 1 | D-1 | 0.7 | 7 |
| Example 2 | A-2 | 0.5 | B-1 | 1 | D-1 | 0.7 | 7 |
| Example 3 | A-2 | 1 | B-1 | 1 | D-1 | 0.7 | 7 |
| Example 4 | A-2 | 3 | B-1 | 1 | D-1 | 0.7 | 7 |
| Example 5 | A-3 | 0.5 | B-1 | 1 | D-1 | 0.7 | 7 |
| Example 6 | A-3 | 1 | B-1 | 1 | D-1 | 0.7 | 7 |
| Example 7 | A-3 | 3 | B-1 | 1 | D-1 | 0.7 | 7 |
| Example 8 | A-4 | 0.5 | B-1 | 1 | D-1 | 0.7 | 7 |
| Example 9 | A-4 | 1 | B-1 | 1 | D-1 | 0.7 | 7 |
| Example 10 | A-4 | 3 | B-1 | 1 | D-1 | 0.7 | 7 |
| Example 11 | A-1 | 1 | B-2 | 0.5 | D-1 | 0.7 | 7 |
| Example 12 | A-1 | 1 | B-3 | 3 | D-1 | 0.7 | 7 |
| Example 13 | A-1 | 1 | B-4 | 2 | D-1 | 0.7 | 7 |
| Example 14 | A-1 | 1 | B-4 | 1 | D-1 | 0.7 | 7 |
| Example 15 | A-1 | 1 | B-5 | 1 | D-1 | 0.7 | 7 |
| Example 16 | A-1 | 1 | B-6 | 0.5 | D-1 | 0.7 | 7 |
| Example 17 | A-1 | 1 | B-7 | 0.7 | D-1 | 0.7 | 7 |
| Example 18 | A-1 | 1 | B-8 | 1 | D-1 | 0.7 | 7 |
| Example 19 | A-1 | 1 | B-9 | 3 | D-1 | 0.7 | 7 |
| Example 20 | A-1 | 1 | B-10 | 3 | D-1 | 0.7 | 7 |
| Example 21 | A-1 | 1 | B-11 | 2 | D-1 | 0.7 | 7 |
| Example 22 | A-1 | 0.1 | B-1 | 1 | D-1 | 0.7 | 7 |
| Example 23 | A-1 | 0.3 | B-1 | 1 | D-1 | 0.7 | 7 |
| Example 24 | A-1 | 4 | B-1 | 1 | D-1 | 0.7 | 7 |
| Example 25 | A-1 | 5 | B-1 | 1 | D-1 | 0.7 | 7 |
| Example 26 | A-1 | 1 | B-1 | 0.1 | D-1 | 0.7 | 7 |
| Example 27 | A-1 | 1 | B-1 | 0.3 | D-1 | 0.7 | 7 |
| Example 28 | A-1 | 1 | B-1 | 4 | D-1 | 0.7 | 7 |
| Example 29 | A-1 | 1 | B-1 | 5 | D-1 | 0.7 | 7 |
| Example 30 | A-1 | 1 | B-1 | 1 | D-1 | 0.5 | 6 |
| Example 31 | A-1 | 1 | B-1 | 1 | D-1 | 1 | 7.5 |

TABLE 2

| | | | | | Hydroxide of | | |
|---|---|---|---|---|---|---|---|
| | | | | | quaternary alkyl | | |
| | Periodic acid | | Cation | | ammonium | | |
| | Component | Content | Component | Content | Component | Content | pH |
| Comparative | A-1 | 1 | C-1 | 1 | D-1 | 0.7 | 7 |
| Example 1 | | | | | | | |
| Comparative | A-1 | 1 | C-2 | 1 | D-1 | 0.7 | 7 |
| Example 2 | | | | | | | |
| Comparative | A-1 | 1 | C-3 | 1 | D-1 | 0.7 | 7 |
| Example 3 | | | | | | | |
| Comparative | A-1 | 1 | C-4 | 1 | D-1 | 0.7 | 7 |
| Example 4 | | | | | | | |
| Comparative | A-1 | 1 | C-5 | 1 | D-1 | 0.7 | 7 |
| Example 5 | | | | | | | |
| Comparative | A-1 | 1 | — | — | — | — | 2 |
| Example 6 | | | | | | | |
| Comparative | A-1 | 1 | — | — | D-1 | 0.7 | 7 |
| Example 7 | | | | | | | |
| Comparative | A-1 | 0.05 | B-1 | 1 | D-1 | 0.7 | 7 |
| Example 8 | | | | | | | |
| Comparative | A-1 | 7 | B-1 | 1 | D-1 | 1 | 7 |
| Example 9 | | | | | | | |
| Comparative | — | — | B-1 | 1 | D-1 | 0.5 | 7 |
| Example 10 | | | | | | | |
| Comparative | A-1 | 1 | B-1 | 1 | D-1 | 0.01 | 3 |
| Example 11 | | | | | | | |
| Comparative | A-1 | 1 | B-1 | 1 | D-1 | 0.05 | 5 |
| Example 12 | | | | | | | |
| Comparative | A-1 | 1 | B-1 | 1 | D-1 | 0.07 | 5.5 |
| Example 13 | | | | | | | |
| Comparative | A-1 | 1 | B-1 | 1 | D-1 | 2.3 | 8 |
| Example 14 | | | | | | | |
| Comparative | A-1 | 1 | B-1 | 1 | D-1 | 3 | 10 |
| Example 15 | | | | | | | |
| Comparative | A-1 | 1 | B-1 | 0.05 | D-1 | 0.7 | 7 |
| Example 16 | | | | | | | |
| Comparative | A-1 | 1 | B-1 | 7 | D-1 | 0.7 | 7 |
| Example 17 | | | | | | | |

A-1: Periodic acid
A-2: Potassium periodate
A-3: Tetraethylammonium periodate
A-4: Tetrabutylammonium periodate
B-1: Ammonium acetate
B-2: Ammonium sulfate
B-3: Ammonium sulfamate
B-4: Ammonium formate
B-5: Ammonium oxalate
B-6: Ammonium benzoate
B-7: Ammonium persulfate
B-8: Ammonium carbonate
B-9: Ammonium carbamate
B-10: Ammonium chloride
B-11: Ammonium phosphate
C-1: Tetramethylammonium acetate
C-2: Tetraethylammonium acetate
C-3: Tetrabutylammonium acetate
C-4: Ethyl acetate
C-5: Benzyl acetate
D-1: Tetramethylammonium hydroxide

### Experimental Example

(1) Evaluation of Ruthenium Film Etch Rate

Specimens were prepared by cutting a wafer on which ruthenium was deposited to a thickness of 300 Å on a ruthenium wafer into fragments with dimensions of 3.0 cm×3.0 cm. Each specimen was immersed in the etchant compositions of Examples 1 to 31 and Comparative Examples 1 to 17 for 1 minute under conditions of 23° C. and 400 rpm. Next, each specimen was taken out, washed with water, and dried using air. Then, the thickness of the ruthenium film that remained after etching was measured through XRF analysis, and the etch rate of the ruthenium film was calculated on the basis of a change in film thickness. The etch rate was evaluated according to the following criteria, and the evaluation results are shown in Tables 3 and 4 below.

Evaluation Criteria

⊚: Etch rate of 300 Å/min or more

∘: Etch rate in a range of from 250 Å/min to less than 300 Å/min

Δ: Etch rate in a range of from 200 Å/min to less than 200 Å/min

X: Etch rate of 200 Å/min or less

(2) Evaluation of RuO₄ Gas Generation

50 mL of each of the etchant compositions of Examples 1 to 31 and the etchant compositions of Comparative Examples exhibiting a ruthenium film etch rate of 200 Å/min or more was put into a bottle, and each specimen having dimensions of 1.5 cm×1.5 cm cut from a wafer on which a 300 Å-thick ruthenium film was deposited was put into one of the bottles. After putting the specimen into the bottle, the inlet of the bottle was sealed with a lid provided with a copper film, the bottle was left at room temperature for 3 hours, and whether the copper film was tarnished was visually checked. In the case of compositions exhibiting a ruthenium film etch rate of less than 200 Å/min, it was not considered that the ruthenium film was substantially etched. In this case, since byproducts including RuO₄ are not generated, evaluation was not performed on such compositions. Whether or not RuO₄ gas was generated was evaluated according to the following criteria, and the results are shown in Tables 3 and 4 below.

Evaluation Criteria

∘: Copper film was tarnished (RuO₄ gas was generated)

X: Copper film was not tarnished (RuO₄ gas was not generated)

(3) Evaluation of Storage Stability

The etchant compositions of Examples 1 to 31 and Comparative Examples 1 to 17 used in Experimental Example (1) were stored at 23° C. for 3 months. After the 3 months of storage, the ruthenium film etch rate of each of the etchant compositions of Comparative Examples 1 to 17 and Examples 1 to 31 was measured again, and the storage stability was evaluated by calculating a change in the etch rate reduction rate of the ruthenium film before and after the storage. The storage stability was evaluated according to the following criteria, and the evaluation results are shown in Tables 3 and 4 below.

Evaluation Criteria

⊚: Reduction in etch rate is 0%

∘: Reduction in etch rate is in a range of from more than 0% to 3%

Δ: Reduction in etch rate is in a range of more than 3% to less than 5%

X: Reduction in etch rate exceeds 5%

(4) Evaluation of Solubility

Solubility of components included in each of the etchant compositions of Examples 1 to 31 and Comparative Examples 1 to 17 was evaluated. Recrystallization/precipitation may occur when the content ratio of the components is not appropriate and thus the solubility of each of the components is low. The reduced mixing stability may increase the possibility of impurity generation in an etching process. The solubility of each of the components in each etchant composition was determined by analyzing the transparency of each etchant composition using UV-Vis spectroscopy equipment, and the specific evaluation criteria are as follows. The obtained results are shown in Table 3 and FIG. 4.

Evaluation Criteria

⊚: 100%

∘: 98% or more to less than 100%

Δ: 95% or more to less than 98%

X: less than 95%

TABLE 3

| | Etch rate of | RuO₄ gas | | |
|---|---|---|---|---|
| | ruthenium film | generation | Storage stability | Solubility |
| Example 1 | ⊚ | X | ⊚ | ⊚ |
| Example 2 | ⊚ | X | ⊚ | ⊚ |
| Example 3 | ⊚ | X | ⊚ | ⊚ |
| Example 4 | ⊚ | X | ⊚ | ⊚ |
| Example 5 | ⊚ | X | ⊚ | ⊚ |
| Example 6 | ⊚ | X | ⊚ | ⊚ |
| Example 7 | ⊚ | X | ⊚ | ⊚ |
| Example 8 | ⊚ | X | ⊚ | ⊚ |
| Example 9 | ⊚ | X | ⊚ | ⊚ |
| Example 10 | ⊚ | X | ⊚ | ⊚ |
| Example 11 | ⊚ | X | ⊚ | ⊚ |
| Example 12 | ⊚ | X | ⊚ | ⊚ |
| Example 13 | ⊚ | X | ⊚ | ⊚ |
| Example 14 | ⊚ | X | ⊚ | ⊚ |
| Example 15 | ⊚ | X | ⊚ | ⊚ |
| Example 16 | ⊚ | X | ⊚ | ⊚ |
| Example 17 | ⊚ | X | ⊚ | ⊚ |
| Example 18 | ⊚ | X | ⊚ | ⊚ |
| Example 19 | ⊚ | X | ⊚ | ⊚ |
| Example 20 | ⊚ | X | ⊚ | ⊚ |
| Example 21 | ⊚ | X | ⊚ | ⊚ |
| Example 22 | ○ | X | ⊚ | ⊚ |
| Example 23 | ○ | X | ⊚ | ⊚ |
| Example 24 | ⊚ | X | ○ | ○ |
| Example 25 | ⊚ | X | ○ | ○ |
| Example 26 | ○ | X | ⊚ | ⊚ |
| Example 27 | ○ | X | ⊚ | ⊚ |
| Example 28 | ⊚ | X | ○ | ○ |
| Example 29 | ⊚ | X | ○ | ○ |
| Example 30 | ⊚ | X | ⊚ | ⊚ |
| Example 31 | ⊚ | X | ⊚ | ⊚ |

TABLE 4

| | Etch rate of | RuO₄ gas | | |
|---|---|---|---|---|
| | ruthenium film | generation | Storage stability | Solubility |
| Comparative | X | — | Δ | ○ |
| Example 1 | | | | |
| Comparative | X | — | Δ | ○ |
| Example 2 | | | | |
| Comparative | X | — | Δ | ○ |
| Example 3 | | | | |
| Comparative | X | — | Δ | ○ |
| Example 4 | | | | |
| Comparative | X | — | Δ | ○ |
| Example 5 | | | | |
| Comparative | Δ | ○ | Δ | ○ |
| Example 6 | | | | |
| Comparative | X | — | Δ | ⊚ |
| Example 7 | | | | |
| Comparative | X | — | ⊚ | ⊚ |
| Example 8 | | | | |
| Comparative | ⊚ | ○ | ⊚ | ○ |
| Example 9 | | | | |
| Comparative | X | — | ○ | ○ |
| Example 10 | | | | |
| Comparative | Δ | ○ | ○ | ○ |
| Example 11 | | | | |
| Comparative | Δ | ○ | ○ | ○ |
| Example 12 | | | | |
| Comparative | Δ | ○ | ○ | ○ |
| Example 13 | | | | |
| Comparative | X | — | Δ | ⊚ |
| Example 14 | | | | |
| Comparative | X | — | X | ⊚ |
| Example 15 | | | | |
| Comparative | X | — | ⊚ | ⊚ |
| Example 16 | | | | |
| Comparative | X | — | ○ | ⊚ |
| Example 17 | | | | |

Referring to Tables 3 and 4, each of the etchant compositions of Examples 1 to 31 included periodic acid and ammonium ions and has a pH that is 6 or more and 7.5 or less. Each of the ruthenium etchant compositions exhibited a ruthenium film etch rate as high as 250 Å/min or more, did not generate RuO₄ gas, and had excellent storage stability and solubility.

On the other hand, in the case of using the etchant compositions of Comparative Examples 1 to 17 in which the content of periodic acid was outside the range of 0.1% to 5% by weight based on the total weight of the etchant composition, the content of ammonium ions was outside the range of 0.1% to 5% by weight based on the total weight of the etchant composition, or the pH was outside the range of from 6 to 7, the ruthenium film etch rate was as low as less than 200 Å/min, RuO₄ gas was generated, or storage stability or solubility was poor.

However, the ruthenium etchant compositions according to embodiments of the present disclosure have advantages in that they exhibit a significantly improved etch rate for a ruthenium metal film without generating RuO₄ gas and have improved storage stability at room temperature in a range of 20° C. to 25° C.

What is claimed is:

1. A ruthenium etchant composition comprising periodic acid and ammonium ions and having a pH value in a range of 6 to 7.5.

2. The ruthenium etchant composition of claim 1, further comprising a hydroxide of quaternary alkyl ammonium.

3. The ruthenium etchant composition of claim 1, wherein the composition exhibits a ruthenium metal film etching rate of 200 Å/min or more.

4. The ruthenium etchant composition of claim 1, wherein a reduction in a ruthenium metal film etching rate is 5% or less after 3 months of storage of the ruthenium etchant composition in a temperature range of 20° C. to 25° C.

5. The ruthenium etchant composition of claim 1, comprising 0.1 to 5% by weight of the periodic acid, 0.1 to 5% by weight of the ammonium ions, and a residual amount of water, based on the total weight of the etchant composition.

6. A pattern formation method comprising etching a ruthenium metal film using the ruthenium etchant composition of claim 1.

7. A method of manufacturing an array substrate for a display device, the method comprising the pattern formation method of claim 6.

8. An array substrate for a display device, manufactured by the method of claim 7.
